(19) United States
(12) Patent Application Publication
(10) Pub. No.: US 2026/0182181 A1
(43) Pub. Date: Jun. 25, 2026

(54) DISPLAY DEVICE AND ELECTRONIC DEVICE

(71) Applicant: SAMSUNG DISPLAY CO., LTD., YONGIN-SI (KR)

(72) Inventors: GUNHO LEE, Yongin-si (KR); EUI JUNG KWON, Yongin-si (KR); GUI-NAM MIN, Yongin-si (KR)

(21) Appl. No.: 19/320,004

(22) Filed: Sep. 5, 2025

(30) Foreign Application Priority Data
Dec. 24, 2024 (KR) 10-2024-0195119

(51) Int. Cl. H10K 59/131; H10K 59/124

(52) U.S. Cl. CPC H10K 59/131; H10K 59/124

(57) ABSTRACT

A display device includes a base layer having a first area with a display area, a second area spaced from the first area in a first direction, and a bending area between them. A first wiring line overlaps the second area and extends in the first direction. A second wiring line overlaps the bending area and is electrically connected to the first wiring line. An inorganic insulation layer is disposed on the first wiring line and includes an opening that overlaps a contact part connecting the first and second wiring lines. The opening is defined by a first side surface extending in the first direction, a second side surface extending in a second direction crossing the first direction, and a third side surface connecting the first and second side surfaces and having a curved shape.

### CROSS-REFERENCE TO RELATED APPLICATIONS

This application claims priority under 35 U.S.C. § 119 to Korean Patent Application No. 10-2024-0195119 filed on Dec. 24, 2024, in the Korean Intellectual Property Office, the disclosures of which are incorporated by reference herein in their entireties.

### TECHNICAL FIELD

Embodiments of the present disclosure relate to a display device and an electronic device, and more particularly, to a display device and an electronic device having improved reliability.

### DISCUSSION OF RELATED ART

Display devices such as, for example, televisions, monitors, smartphones, and tablets, use display panels to provide images to users. Various types of display panels have been developed including, for example, liquid crystal display panels, organic light-emitting display panels, electro-wetting display panels, and electrophoretic display panels.

A touch insulation layer may include an inorganic insulation layer and an organic insulation layer. In this case, the inorganic insulation layer may also be disposed in a pad area, in which the pads are disposed. When the inorganic insulation layer is oxidized, hydrogen radicals and ammonia gases may be discharged. When the hydrogen radicals and the ammonia gases reach a lower conductive layer, the lower conductive layer may also be oxidized.

### SUMMARY

Embodiments of the present disclosure provide a display device and an electronic device that may prevent cracks from being generated in an inorganic layer that is adjacent to a bending area, or reduce cracks, resulting in a display device having improved reliability.

According to an embodiment, a display device includes a base layer including a first area including a display area, a second area spaced apart from the first area in a first direction, and a bending area disposed between the first area and the second area, a first wiring line overlapping the second area and extending in the first direction, a second wiring line overlapping the bending area and electrically connected to the first wiring line, and an inorganic insulation layer disposed on the first wiring line, and in which an opening overlapping a contact part, in which the first wiring line and the second wiring line are connected to each other, is defined. The inorganic insulation layer includes a first side surface extending in the first direction, a second side surface extending in a second direction crossing the first direction, and a third side surface connecting the first side surface and the second side surface, and having a curved shape in a plan view. The opening is defined by the first to third side surfaces.

According to an embodiment, a display device includes a base layer including a first area, a second area spaced apart from the first area in a first direction, and a bending area disposed between the first area and the second area, a first wiring line overlapping the second area and extending in the first direction, a second wiring line overlapping the bending area and electrically connected to the first wiring line, and an inorganic insulation layer disposed on the first wiring line, and in which an opening overlapping the bending area is defined. The inorganic insulation layer includes a first side surface extending in the first direction, and a second side surface extending in a second direction crossing the first direction. The second side surface is spaced apart from the bending area in the first direction in a plan view.

According to an embodiment, an electronic device includes a housing, an electronic module disposed inside the housing, and a display device disposed on and overlapping the electronic module. The display device includes a base layer including a first area, a second area spaced apart from the first area in a first direction, and a bending area disposed between the first area and the second area, a first wiring line overlapping the second area and extending in the first direction, a second wiring line overlapping the bending area and electrically connected to the first wiring line, and an inorganic insulation layer disposed on the first wiring line, and in which an opening overlapping a contact part, in which the first wiring line and the second wiring line are connected to each other, is defined. The inorganic insulation layer includes a first side surface extending in the first direction, a second side surface extending in a second direction crossing the first direction, and a third side surface connecting the first side surface and the second side surface, and having a curved shape in a plan view. The opening is defined by the first to third side surfaces.

### BRIEF DESCRIPTION OF THE DRAWINGS

The above and other objects and features of the present disclosure will become more apparent by describing in detail embodiments thereof with reference to the accompanying drawings.

FIG. 1A is a block diagram of an electronic device according to an embodiment of the present disclosure.

FIGS. 1B to 1D illustrate an electronic device according to embodiments of the present disclosure.

FIG. 2 is a perspective view of an electronic device according to an embodiment of the present disclosure.

FIG. 3 is a perspective view of an electronic device according to an embodiment of the present disclosure, illustrating a folded state of the electronic device of FIG. 2.

FIG. 4 is a perspective view of an electronic device according to an embodiment of the present disclosure, illustrating a folded state of the electronic device of FIG. 2.

FIG. 5 is an exploded perspective view of an electronic device according to an embodiment of the present disclosure.

FIGS. 6A and 6B are cross-sectional views of a display module according to an embodiment.

FIG. 7 is a cross-sectional view of a display module according to an embodiment of the present disclosure.

FIG. 8 is a plan view of a display panel according to an embodiment of the present disclosure.

FIG. 9A is an enlarged view of a portion of a display panel according to an embodiment of the present disclosure.

FIG. 9B is a cross-sectional view of a display device according to an embodiment of the present disclosure.

FIG. 10 is an enlarged view of area CC′ illustrated in FIG. 9A.

FIG. 11 is an enlarged view of a portion of a display panel according to an embodiment of the present disclosure.

FIG. 12 is an enlarged view of a portion of a display panel according to an embodiment of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ±30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

The term “and/or” includes one or more combinations in each of which associated elements are defined.

It will be understood that the terms “include”, “comprise”, “have”, and the like specify the presence of features, numbers, steps, operations, elements, or components, described in the specification, or a combination thereof, not precluding the presence or additional possibility of one or more other features, numbers, steps, operations, elements, or components or a combination thereof.

A flexible display device is often subject to mechanical stress, for example, in regions that undergo repeated bending. In such devices, wiring lines should extend across bending areas to maintain electrical connectivity between different functional regions. However, stress concentration at connection points between these wiring lines, including at locations where they are covered by brittle inorganic insulation layers, can lead to cracking and degradation over time.

Embodiments of the present disclosure address this issue by providing a display device in which an inorganic insulation layer, disposed over the wiring connection region in or near a bending area, includes a curved side surface when viewed in a plan view. The curved geometry of the opening in the insulation layer may aid in distributing mechanical stress more evenly during bending, which may reduce the likelihood of crack formation and improve reliability.

By implementing this structure, a display device according to embodiments of the present disclosure may maintain electrical continuity across bendable regions while improving long-term durability of the wiring lines and surrounding insulation materials.

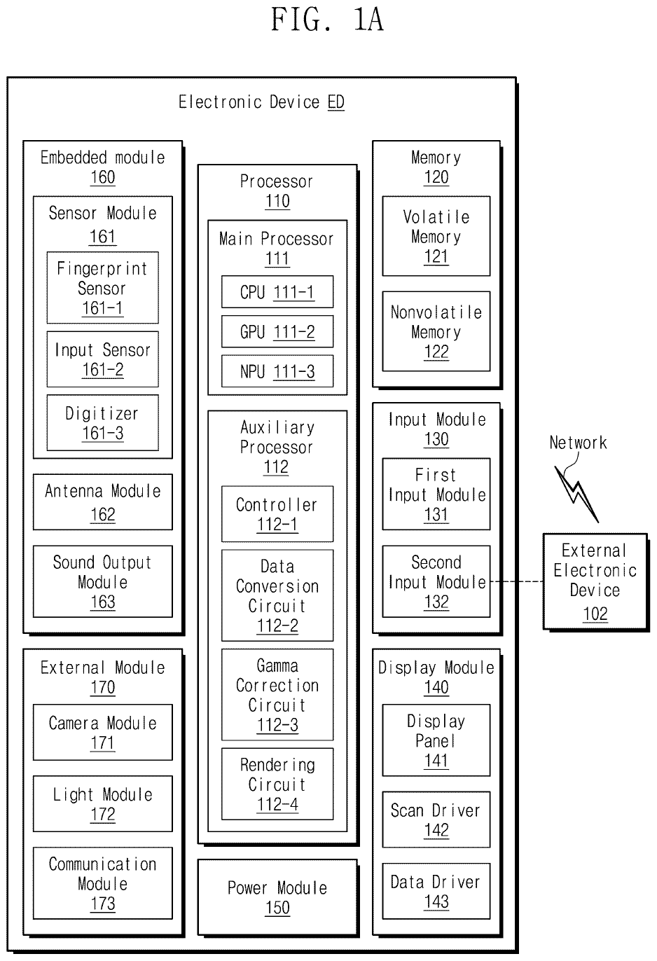

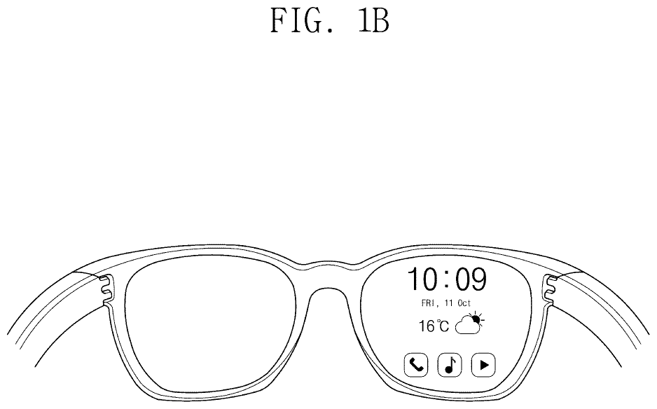

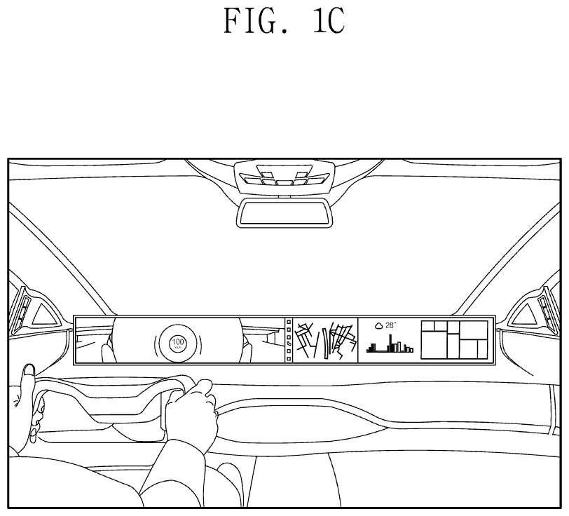

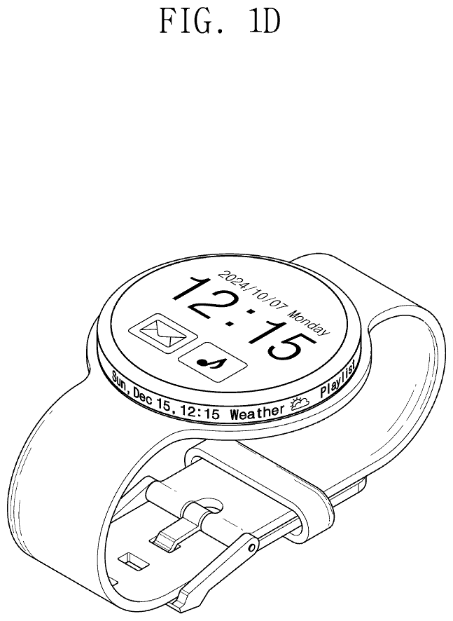

FIG. 1A is a block diagram of an electronic device according to an embodiment of the present disclosure. FIGS. 1B to 1D illustrate an electronic device according to embodiments of the present disclosure.

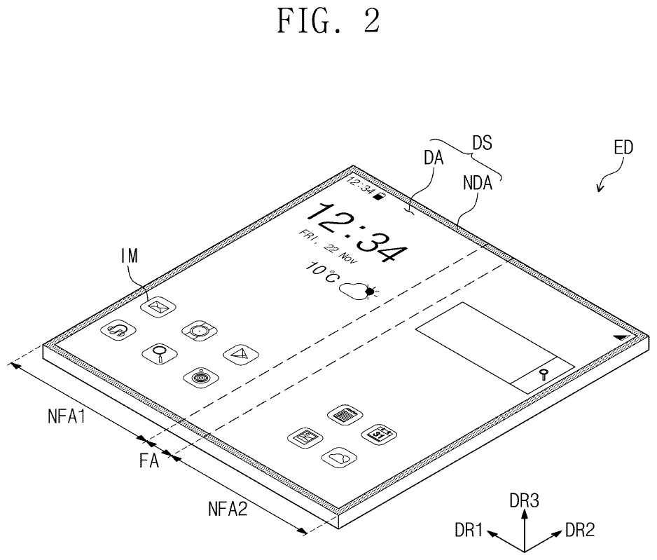

An electronic device ED according to an embodiment of the present disclosure includes a display device DD. The electronic device ED according to an embodiment of the present disclosure may be a foldable phone as illustrated in FIGS. 2 to 4, but is not limited thereto.

As illustrated in FIG. 1A, the electronic device ED outputs a variety of information through a display module 140 in an operating system. When a processor 110 executes an application stored in a memory 120, the display module 140 provides the user with application information through a display panel 141.

The processor 110 obtains an external input through an input module 130 or a sensor module 161 and executes an application corresponding to the external input. For example, when the user selects a camera icon displayed in the display panel 141, the processor 110 obtains the user input through an input sensor 161-2 and activates a camera module 171. The processor 110 transfers image data corresponding to a photographed image obtained through the camera module 171 to the display module 140. The display module 140 may display an image corresponding to the photographed image through the display panel 141.

As another example, when authentication for personal information is performed in the display module 140, a fingerprint sensor 161-1 obtains the input fingerprint information as input data. The processor 110 compares the input data obtained through the fingerprint sensor 161-1 and authentication data stored in the memory 120 and executes an application depending on a comparison result. The display module 140 may display information executed depending on logic of the application, through the display panel 141.

As another example, when the user selects a music streaming icon displayed in the display module 140, the processor 110 obtains the user input through the input sensor 161-2 and activates a music streaming application stored in the memory 120. When a music play command is input to the music streaming application, the processor 110 activates a sound output module 163 and provides the user with sound information corresponding to the music play command.

The operation of the electronic device ED is briefly described above. Below, a configuration of the electronic device ED will be described in detail. Some of components of the electronic device ED to be described further below may be integrally implemented with one component, and the one component may be divided into two or more components.

Referring to FIG. 1A, the electronic device ED may communicate with an external electronic device 102 over a network (e.g., a short-range wireless communication network or a long-range wireless communication network). According to an embodiment, the electronic device ED may include the processor 110, the memory 120, the input module 130, the display module 140, a power module 150, an embedded module (or an internal module) 160, and an external module 170. According to an embodiment, the electronic device ED may not include at least one of the above components or may further include one or more other components. According to an embodiment, some of the above components (e.g., the sensor module 161, an antenna module 162, or the sound output module 163) may be integrated into any other component (e.g., the display module 140).

The processor 110 may execute software to control at least one component (e.g., a hardware or software component) of the electronic device ED connected with the processor 110 and may perform various data processing or operations. According to an embodiment, as at least a part of the data processing or operations, the processor 110 may store a command or data received from any other component (e.g., the input module 130, the sensor module 161, or a communication module 173) in a volatile memory 121, may process the command or data stored in the volatile memory 121, and may store the processed data in a nonvolatile memory 122.

The processor 110 may include a main processor 111 and an auxiliary processor 112. The main processor 111 may include one or more of a central processing unit (CPU) 111-1 or an application processor (AP). The main processor 111 may further include one or more of a graphic processing unit (GPU) 111-2, a communication processor (CP), and an image signal processor (ISP). The main processor 111 may further include a neural processing unit 111-3 (NPU) 111-3. The neural processing unit may be a processor specialized for processing of an artificial intelligence model, and the artificial intelligence model may be created through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the above-described networks, but may not be limited to the above-described example. In addition to a hardware structure, additionally or alternatively, the artificial intelligence model may include a software structure. At least two of the above processing units and processors may be integrally implemented with one component (e.g., a single chip), or each of the above processing units and processors may be implemented with an independent component (e.g., a plurality of chips).

The auxiliary processor 112 may include a controller 112-1. The controller 112-1 may include an interface conversion circuit and a timing control circuit. The controller 112-1 receives an image signal from the main processor 111 and outputs image data obtained by converting a data format of the image signal so as to be suitable for the specification of an interface with the display module 140. The controller 112-1 may output various kinds of control signals necessary to drive the display module 140.

The auxiliary processor 112 may further include a data conversion circuit 112-2, a gamma correction circuit 112-3, a rendering circuit 112-4, etc. The data conversion circuit 112-2 may receive image data from the controller 112-1; the data conversion circuit 112-2 may compensate for the image data such that an image is displayed with a desired luminance depending on a characteristic of the electronic device ED or user settings or may convert the image data to reduce power consumption or to compensate for afterimages. The gamma correction circuit 112-3 may convert the image data or the gamma reference voltage such that an image displayed on the electronic device ED has a desired gamma characteristic. The rendering circuit 112-4 may receive the image data from the controller 112-1 and may render the image data in consideration of a pixel arrangement of the display panel 141 applied to the electronic device ED. At least one of the data conversion circuit 112-2, the gamma correction circuit 112-3, and the rendering circuit 112-4 may be integrated into any other component (e.g., the main processor 111 or the controller 112-1). At least one of the data conversion circuit 112-2, the gamma correction circuit 112-3, and the rendering circuit 112-4 may be integrated into a data driver 143 to be described further below.

The memory 120 may store various data used by at least one component (e.g., the processor 110 or the sensor module 161) of the electronic device ED and input data or output data for commands related thereto. The memory 120 may include at least one of the volatile memory 121 and the nonvolatile memory 122.

The input module 130 may receive a command or data to be used by a component (e.g., the processor 110, the sensor module 161, or the sound output module 163) of the electronic device ED from the outside of the electronic device ED (e.g., the user or the external electronic device 102).

The input module 130 may include a first input module 131 to which a command or data are input from the user and a second input module 132 to which a command or data are input from the external electronic device 102. The first input module 131 may include a microphone, a mouse, a keyboard, a key (e.g., a button), or a pen (e.g., a passive pen or an active pen). The second input module 132 may support a specified protocol capable of connecting to the external electronic device 102 by wire or wirelessly. According to an embodiment, the second input module 132 may include a high definition multimedia interface (HDMI), a universal serial bus (USB) interface, a secure digital (SD) card interface, or an audio interface. The second input module 132 may include a connector capable of being physically connected with the external electronic device 102, for example, an HDMI connector, a USB connector, an SD card connector, or an audio connector (e.g., a headphone connector).

The display module 140 visually provides information to the user. The display module 140 may include a display panel 141, a scan driver 142, and a data driver 143. The display module 140 may further include a window, a chassis, and a bracket that protect the display panel 141.

The display panel 141 may include a liquid crystal display panel, an organic light-emitting display panel, or an inorganic light-emitting display panel, and the type of the display panel 141 is not particularly limited. The display panel 141 may be a rigid type, or a flexible type that may be rolled or folded. The display module 140 may further include a supporter supporting the display panel 141, a bracket, or a heat dissipating member.

The scan driver 142 may be mounted on the display panel 141 as a driving chip. Furthermore, the scan driver 142 may be integrated into the display panel 141. For example, the scan driver 142 may include an amorphous silicon TFT gate driver circuit (ASG), a low temperature polycrystalline silicon (LTPS) TFT gate driver circuit, or an oxide semiconductor TFT gate driver circuit (OSG) internalized in the display panel 141. The scan driver 142 receives a control signal from the controller 112-1 and outputs scan signals to the display panel 141 in response to the control signal.

The display panel 141 may further include an emission driver. The emission driver outputs a light emitting control signal to the display panel 141 in response to the control signal received from the controller 112-1. The emission driver may be formed to be distinguished from the scan driver 142 or may be integrated into the scan driver 142.

The data driver 143 receives a control signal from the controller 112-1, converts image data into analog voltages (e.g., data voltages) in response to the control signal, and outputs data voltages to the display panel 141.

The data driver 143 may be integrated into other components (e.g., the controller 112-1). The functions of the interface conversion circuit and the timing control circuit of the controller 112-1 described above may be integrated into the data driver 143.

The display module 140 may further include an emission driver, a voltage generator, etc. The voltage generator may output various kinds of voltages used to drive the display panel 141.

The power module 150 supplies a power to the components of the electronic device ED. The power module 150 may include a battery that charges a power supply voltage. The battery may include a primary cell that is not rechargeable, a secondary cell that is rechargeable, or a fuel cell. The power module 150 may include a power management integrated circuit (PMIC). The PMIC supplies power used for each of the modules described above and modules to be described further below. The power module 150 may include a wireless power transmission/reception member electrically connected with the battery. The wireless power transmission/reception member may include a plurality of antenna radiators that are in the form of a coil.

The electronic device ED may further include the embedded module 160 and the external module 170. The embedded module 160 may include the sensor module 161, the antenna module 162, and the sound output module 163. The external module 170 may include the camera module 171, a light module 172, and the communication module 173.

The sensor module 161 may sense an input by a user's body or an input by a pen among the first input module 131 and may generate an electrical signal or a data value corresponding to the input. The sensor module 161 may include at least one or more of the fingerprint sensor 161-1, the input sensor 161-2, and a digitizer 161-3.

The fingerprint sensor 161-1 may generate a data value corresponding to the user's fingerprint. The fingerprint sensor 161-1 may include one of an optical fingerprint sensor or a capacitive fingerprint sensor.

The input sensor 161-2 may generate a data value corresponding to coordinate information of the input by the user's body or the input by the pen. The input sensor 161-2 generates a capacitance change due to the input as a data value. The input sensor 161-2 may sense the input by the passive pen or may exchange data with the active pen.

The input sensor 161-2 may measure a biometric signal, such as blood pressure, moisture, or body fat. For example, when the user touches his/her body part to a sensor layer or a sensing panel and does not move during a given time period, the input sensor 161-2 may detect the biometric signal based on a change in an electric field caused by the body part and may output the information desired by the user to the display module 140.

The digitizer 161-3 may generate a data value corresponding to the coordinate information of the input by the pen. The digitizer 161-3 generates the amount of electromagnetic change by the input as a data value. The digitizer 161-3 may sense the input by the passive pen or may exchange data with the active pen.

At least one of the fingerprint sensor 161-1, the input sensor 161-2, and the digitizer 161-3 may be implemented with a sensor layer formed on the display panel 141 through a continuous process. The fingerprint sensor 161-1, the input sensor 161-2, and the digitizer 161-3 may be disposed above/on the display panel 141, and at least one of the fingerprint sensor 161-1, the input sensor 161-2, and the digitizer 161-3, for example, the digitizer 161-3 may be disposed below/under the display panel 141.

At least two or more of the fingerprint sensor 161-1, the input sensor 161-2, and the digitizer 161-3 may be integrally formed with one sensing panel through the same process. When these components are integrally formed with one sensing panel, the sensing panel may be disposed between the display panel 141 and the window disposed above/on the display panel 141. According to an embodiment, the sensing panel may be disposed on the window. However, the location of the sensing panel is not specifically limited.

At least one of the fingerprint sensor 161-1, the input sensor 161-2, and the digitizer 161-3 may be embedded in the display panel 141. That is, at least one of the fingerprint sensor 161-1, the input sensor 161-2, and the digitizer 161-3 may be simultaneously formed through a process of forming elements (e.g., a light-emitting element and transistors) included in the display panel 141.

In addition, the sensor module 161 may generate an electrical signal or a data value corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas to transmit or receive the signal or power to or from an external source. According to an embodiment, the communication module 173 may transmit or receive the signal to or from the external electronic device through the antenna suitable for the communication method. An antenna pattern of the antenna module 162 may be integrated with one component (e.g., the display panel 141) of the display module 140 or the input sensor 161-2.

The sound output module 163 that is a device that outputs a sound signal to the outside of the electronic device ED may include, for example, a speaker used for general purposes such as multimedia playback or recording playback and a receiver used exclusively for receiving calls. According to an embodiment, the receiver and the speaker may be either integrally or separately implemented. A sound output pattern of the sound output module 163 may be integrated with the display module 140.

The camera module 171 may capture a still image or a moving image (e.g., a video). According to an embodiment, the camera module 171 may include one or more lenses, an image sensor, or an image signal processor. The camera module 171 may further include an infrared camera capable of measuring the presence or absence of the user, the location of the user, and the line of sight of the user.

The light module 172 may provide a light. The light module 172 may include a light-emitting diode or a xenon lamp. The light module 172 may operate in conjunction with the camera module 171 or may operate independently.

The communication module 173 may establish a wired or wireless communication channel between the electronic device ED and the external electronic device 102 and may support communication execution through the established communication channel. The communication module 173 may include one of a wireless communication module, such as a cellular communication module, a short-range wireless communication module, or a global navigation satellite system (GNSS) communication module, and a wired communication module, such as a local area network (LAN) communication module or a power line communication module or may include all thereof. The communication module 173 may communicate with the external electronic device 102 over a short-range communication network such as BLUETOOTH, WI-FI direct, or infrared data association (IrDA) or a long-range communication network, such as a cellular network, the Internet, or a computer network (e.g., a LAN or WAN). Various kinds of communication modules 173 described above may be implemented with one chip or with separate chips, respectively.

The input module 130, the sensor module 161, the camera module 171, etc. may be used to control the operation of the display module 140 in conjunction with the processor 110.

The processor 110 outputs commands or data to the display module 140, the sound output module 163, the camera module 171, or the light module 172 based on the input data received from the input module 130. For example, in an embodiment, the processor 110 may generate the image data corresponding to the input data applied through the mouse or the active pen and may output the image data to the display module 140. In an embodiment, the processor 110 may generate command data corresponding to the input data and may output the command data to the camera module 171 or the light module 172. When input data are not received from the input module 130 during a given time period, the processor 110 may switch an operating mode of the electronic device ED to a low-power mode or a sleep mode such that the power consumption of the electronic device ED is reduced.

The processor 110 outputs commands or data to the display module 140, the sound output module 163, the camera module 171, or the light module 172 based on the sensing data received from the sensor module 161. For example, the processor 110 may compare authentication data applied through the fingerprint sensor 161-1 with authentication data stored in the memory 120 and may then execute an application depending on a comparison result. The processor 110 may execute a command based on the sensing data sensed by the input sensor 161-2 or the digitizer 161-3 or may output image data corresponding to the sensing data to the display module 140. When the sensor module 161 includes a temperature sensor, the processor 110 may receive temperature data associated with the measured temperature from the sensor module 161 and may further perform luminance correction on the image data based on the temperature data.

The processor 110 may receive measurement data about the presence or absence of the user, the location of the user, and the line of sight of the user from the camera module 171. The processor 110 may further perform the luminance correction on the image data based on the measurement data. For example, the processor 110 that determines the presence or absence of the user through the input from the camera module 171 may display image data whose luminance is corrected through the data conversion circuit 112-2 or the gamma correction circuit 112-3.

Some of the above components may be connected with each other through a communication scheme between peripheral devices, for example, a bus, a general purpose input/output (GPIO), a serial peripheral interface (SPI), a mobile industry processor interface (MIPI), or an ultra-path interconnect (UPI) link and may exchange signals (e.g., commands or data). The processor 110 may communicate with the display module 140 through a given interface. For example, one of the communication methods described above may be used, and the present disclosure is not limited thereto.

According to various embodiments disclosed in the disclosure, the electronic device ED may include various types of devices. The electronic device ED may include, for example, at least one of a portable communication device (e.g., a smartphone), a tablet device, a portable multimedia device, a wearable device, and home appliances. An electronic device ED according to an embodiment of the disclosure is not limited to the above-described electronic devices ED. For example, augmented reality (AR) glasses illustrated in FIG. 1B, various types of vehicle information providing devices illustrated in FIG. 1C, and a smartwatch illustrated in FIG. 1D may be implemented as the electronic device ED.

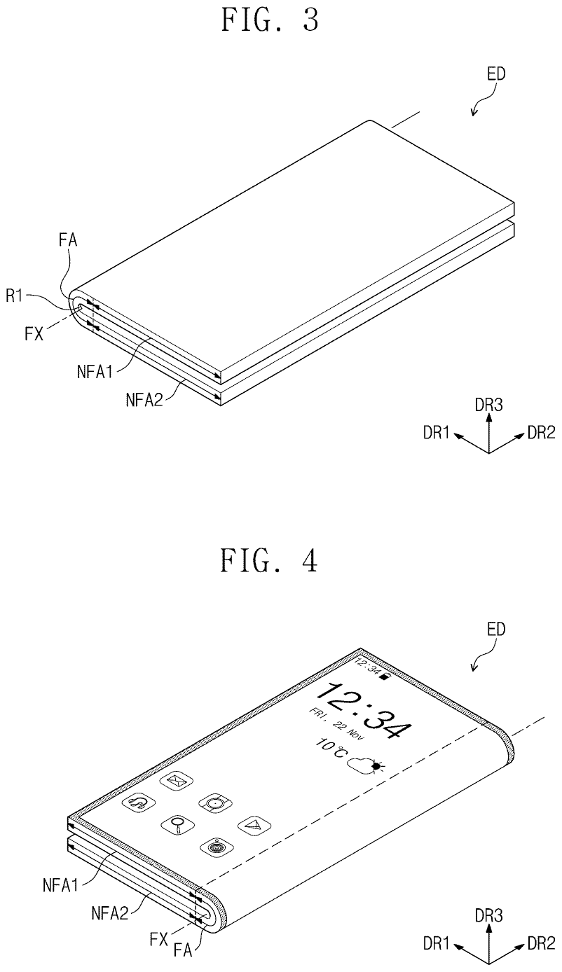

FIG. 2 is a perspective view of an electronic device according to an embodiment of the present disclosure. FIG. 3 is a perspective view of an electronic device according to an embodiment of the present disclosure, illustrating a folded state of the electronic device of FIG. 2. FIG. 4 is a perspective view of an electronic device according to an embodiment of the present disclosure, illustrating a folded state of the electronic device of FIG. 2.

Referring to FIG. 2, the electronic device ED according to an embodiment of the present disclosure may have a rectangular shape having two short sides that extend in a first direction DR1 and two long sides that extend in a second direction DR2 that crosses the first direction DR1. However, the present disclosure is not limited thereto, and the electronic device ED may have various shapes such as, for example, a circle or a polygon.

Hereinafter, a direction that is substantially perpendicular to a plane defined by the first direction DR1 and the second direction DR2 is defined as a third direction DR3. Furthermore, in the specification, the phrase “when viewed on a plane” may be defined as a state in which the object is viewed from the third direction DR3. For example, the phrase “when viewed on a plane” may mean when viewed in a plan view.

A thickness direction of the electronic device ED may correspond to the third direction DR3, which is a normal direction with respect to a plane defined by the first direction DR1 and the second direction DR2. In the specification, front surfaces (or top surfaces) and rear surfaces (or lower surfaces) of members that constitute the electronic device ED may be defined with respect to the third direction DR3. In the specification, “a thickness” may represent a value that is measured in the third direction DR3, and “a width” may represent a value that is measured in the first direction DR1 or the second direction DR2, which is a horizontal direction.

The electronic device ED according to an embodiment may include a flat display surface DS. Images IM generated by the electronic device ED may be provided to the user through a display surface DS. The display surface DS may include a plane that is defined by the first direction DR1 and the second direction DR2. However, the present disclosure is not limited thereto, and the display surface DS may further include a curved surface that is bent from at least one side of a plane defined by the first direction DR1 and the second direction DR2.

The display surface DS may include a display area DA, and a non-display area NDA around the display area DA. In an embodiment, an image may be displayed in the display area DA, and an image is not displayed in the non-display area NDA. The non-display area NDA may surround the display area DA. However, the present disclosure is not limited thereto, and the shape of the display area DA and the shape of the non-display area NDA may be modified. In an embodiment, the non-display area NDA may be omitted.

Referring to FIGS. 2 to 4, the electronic device ED according to an embodiment of the present disclosure may be a foldable electronic device.

The electronic device ED may include a folding area FA and a plurality of non-folding areas NFA1 and NFA2. For example, the non-folding areas NFA1 and NFA2 may include a first non-folding area NFA1 and a second non-folding area NFA2. The folding area FA may be disposed between the first non-folding area NFA1 and the second non-folding area NFA2. The folding area FA, the first non-folding area NFA1, and the second non-folding area NFA2 may be arranged in the second direction DR2. By way of example, one folding area FA and two non-folding areas NFA1 and NFA2 are illustrated, but the numbers of the folding areas FA and the non-folding areas NFA1 and NFA2 are not limited thereto. For example, the electronic device ED may include more than two non-folding areas, and a plurality of folding areas that are arranged between the non-folding areas.

As illustrated in FIG. 3, the folding area FA may be folded with respect to a folding axis FX that extends in the second direction DR2. The folding area FA has a specific curvature and a specific radius R1 of curvature. The first non-folding area NFA1 and the second non-folding areas NFA2 may face each other, and the electronic device ED may be in-folded such that the display surface DS is not exposed when folded.

As illustrated in FIG. 4, the folding area FA may be out-folded with respect to the folding axis FX that is parallel to the second direction DR2 such that the display surface DS is exposed when folded.

In an embodiment of the present disclosure, the electronic device ED may be configured such that an in-folding or out-folding operations are repeated from the unfolding operation, but the present disclosure is not limited thereto. In an embodiment of the present disclosure, the electronic device ED may be configured to select any one of the unfolding operation, the in-folding operation, and the out-folding operation.

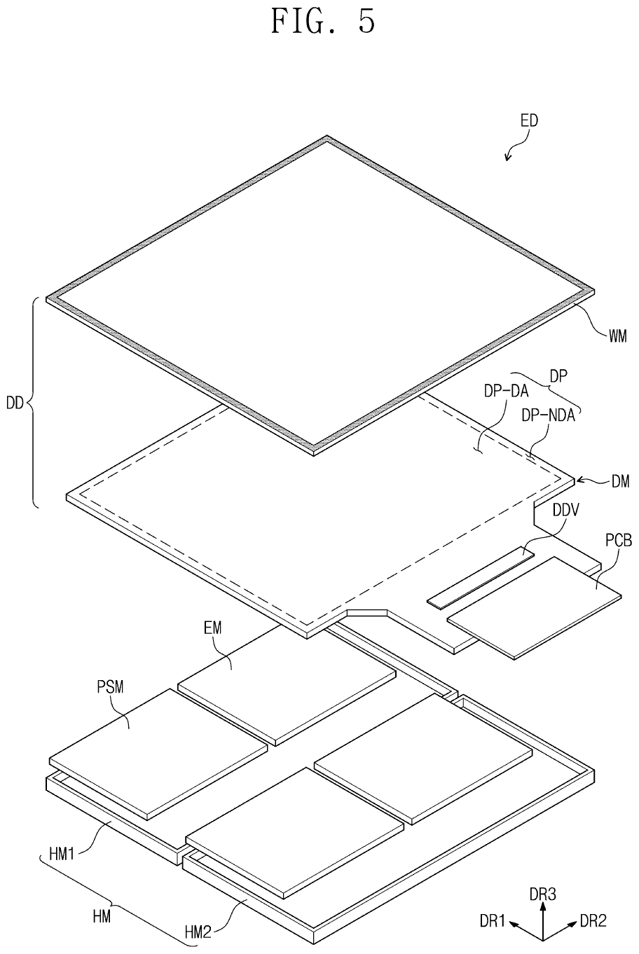

FIG. 5 is an exploded perspective view of an electronic device according to an embodiment of the present disclosure.

Referring to FIG. 5, the electronic device ED may include a display device DD, an electronic module EM, a power module PSM, and a housing HM. In an embodiment, the electronic device ED may further include a mechanical structure that controls the folding operation of the display device DD. The electronic device ED may further include an electro-optical module that outputs or receives an optical signal. The electro-optical module may include a camera module and/or a proximity sensor.

The display device DD generates an image and detects an external input. The display device DD includes a window module WM and a display module DM. The window module WM provides a front surface of the electronic device ED.

The display module DM may include at least one display panel DP. As shown in FIG. 5, the display panel DP is depicted as a representative component of the stacked structure of the display module DM. Although only the display panel DP is illustrated, the display module DM may further include additional structural and functional layers disposed on or above the display panel DP, depending on the implementation. A detailed explanation of the stacked configuration, including such additional layers, is provided further below.

The display panel 100 is not particularly limited thereto, and for example, the display panel 100 may be a light-emitting display panel, such as an organic light-emitting display panel or a quantum dot light-emitting display panel. The display panel DP may be a display panel including an ultra-small light-emitting element, such as a micro LED or a nano LED.

The display panel DP includes a display area DP-DA and a non-display area DP-NDA corresponding to the display area DA (see FIG. 2) and the non-display area NDA (see FIG. 2) of the electronic device ED, respectively. In the specification, “an area/portion corresponds to another area/portion” may mean “the area/portion overlaps the other area/portion.”, but the meaning is not limited thereto.

As illustrated in FIG. 5, a driver DDV may be disposed in the non-display area DP-NDA of the display panel DP. A printed circuit board PCB may be coupled to the non-display area DP-NDA of the display panel DP. The printed circuit board PCB may be connected to the display panel DP with the flexible circuit board interposed therebetween.

The data driver DDV may include driving elements that drive pixels of the display panel DP, for example, drivers. Although FIG. 5 illustrates a structure in which the data driver DDV is mounted on the display panel DP, the present disclosure is not limited thereto. For example, the data driver DDV may be mounted on the printed circuit board PCB.

The electronic module EM may include, for example, a control module, a wireless communication module, an image input module, a sound input module, a sound output module, a memory, an external interface module, and the like. The modules may be mounted on the printed circuit board PCB or may be electrically connected to the printed circuit board PCB through a flexible circuit board. The electronic module EM may be electrically connected to the power module PSM.

The electronic module EM may be disposed in each of the first housing HM1 and the second housing HM2, and the power module PSM may be disposed in each of the first housing HM1 and the second housing HM2. The electronic module EM disposed in the first housing HM1 and the electronic module EM disposed in the second housing HM2 may be electrically connected to each other through a flexible circuit board.

A power supply module PSM supplies power used for overall operations of the electronic device ED. The power supply module PSM may include a general battery device.

The housing HM is coupled to the display device DD (e.g., to the window module WM) to accommodate the other modules. Although it is illustrated that the housing HM includes first and second housings HM1 and HM2 that are separated from each other, the present disclosure is not limited thereto. The electronic device ED may further include a hinge structure that connects the first and second housings HM1 and HM2.

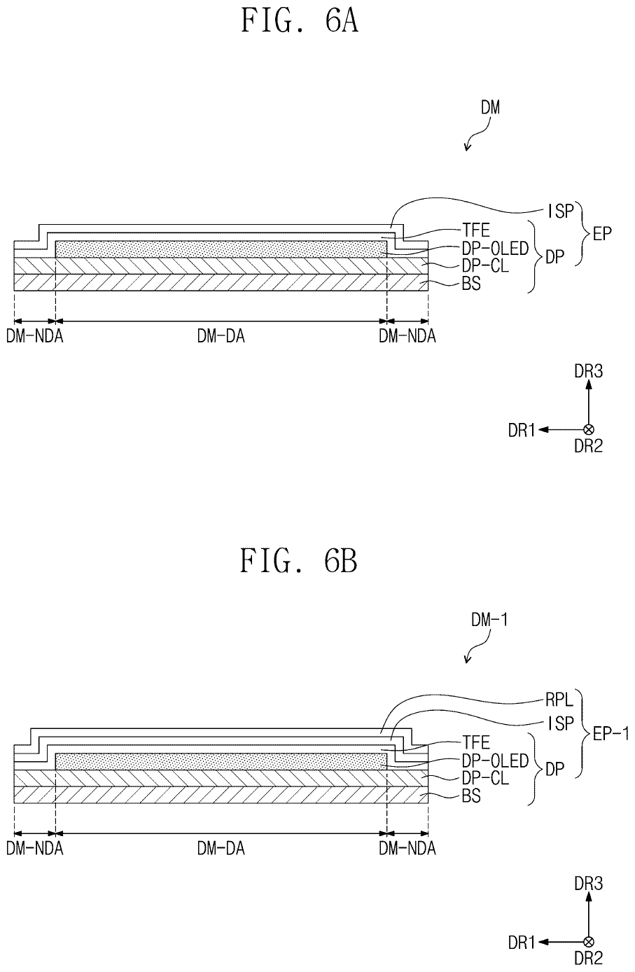

FIGS. 6A and 6B are cross-sectional views of a display module according to an embodiment.

Referring to FIG. 6A, the display module DM according to an embodiment of the present disclosure may include an electronic panel EP. The electronic panel EP may include a display panel DP and an input sensor ISP disposed on the display panel DP. The display panel DP may include a base layer BS, a circuit layer DP-CL disposed on the base layer BS, a light-emitting element layer DP-OLED disposed on the circuit layer DP-CL, and a thin film encapsulation layer TFE disposed on the light-emitting element layer DP-OLED.

The display panel DP according to an embodiment of the present disclosure may be a light-emitting display panel, and is not particularly limited thereto. For example, the display panel DP may be an organic light-emitting display panel or an inorganic light-emitting display panel. A light emission layer of the organic light-emitting display panel may include an organic light emitting material. The light emission layer of the inorganic light-emitting display panel may include a quantum dot or a quantum rod. Furthermore, the light emission layer of the display panel DP may include a micro LED element and/or a nano LED element. Hereinafter, the display panel DP will be described as an organic light-emitting display panel.

In the display panel DP, the base layer BS may be a member that provides a base surface on which the light-emitting element layer DP-OLED is disposed. The base layer BS may be, for example, a glass substrate, a metal substrate, a polymer substrate, or the like. However, embodiments are not limited thereto, and the base layer BS may be, for example, an inorganic layer, a functional layer, or a composite material layer.

The base layer BS may have a multi-layered structure. For example, the base layer BS may have a three-layered structure including a polymer resin layer, an adhesion layer, and a polymer resin layer. For example, the polymer resin layer may include a polyimide-based resin. In addition, the polymer resin layer may include at least one of acrylate-based resin, methacrylate-based resin, polyisoprene-based resin, vinyl-based resin, epoxy-based resin, urethane-based resin, cellulose-based resin, siloxane-based resin, polyamide-based resin, and perylene-based resin. As used herein, “a-based” resin in the specification means including the functional group of “a”.

The circuit layer DP-CL may include, for example, an organic layer, an inorganic layer, a semiconductor pattern, a conductive pattern, a signal line, and the like. An organic layer, an inorganic layer, a semiconductor layer, and a conductive layer may be formed on the base layer BS through a method such as, for example, coating or deposition. Thereafter, an organic layer, an inorganic layer, a semiconductor layer, and a conductive layer may be selectively patterned through a plurality of photolithography processes to form a semiconductor pattern, a conductive pattern, and a signal line.

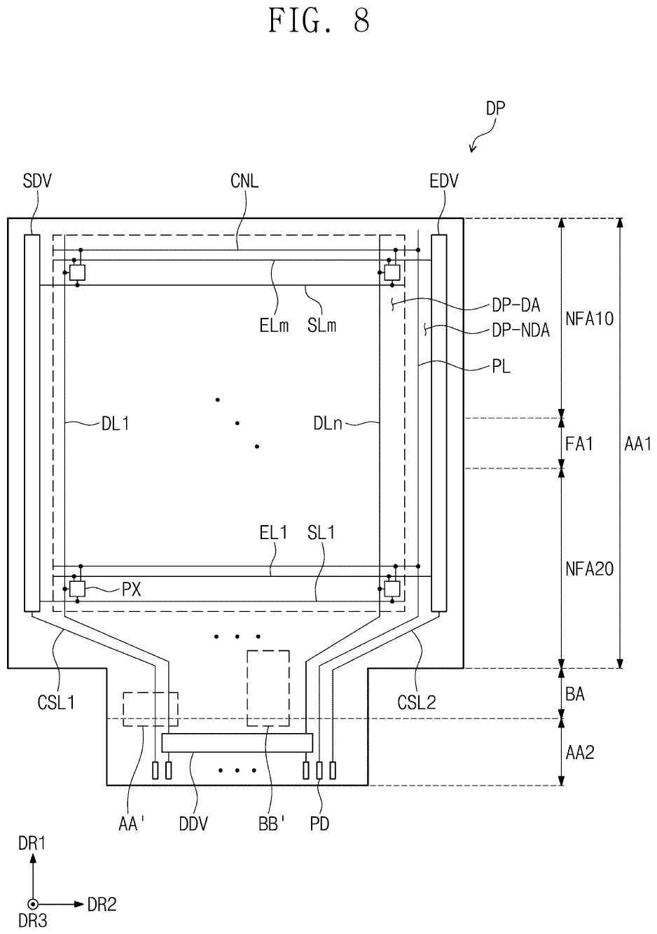

The semiconductor pattern, the conductive pattern, and the signal line may form pixel drivers and signal lines SL1 to SLm, DL1 to DLn, EL1 to ELm, CSL1, CSL2, and PL (see FIG. 8) of the pixels PX (FIG. 8) that will be described below. The pixel driver may include at least one transistor.

The light-emitting element layer DP-OLED includes light-emitting elements of pixels PX (FIG. 8). The light-emitting elements are electrically connected to the at least one transistor. In addition, the light-emitting element layer DP-OLED may further include at least one of an organic layer and an inorganic layer.

A thin film encapsulation layer TFE may be disposed on the circuit layer DP-CL to cover the light-emitting element layer DP-OLED. The thin film encapsulation layer TFE may protect the light-emitting elements from foreign substances such as, for example, moisture/oxygen and dust particles. The thin film encapsulation layer TFE may include, for example, an inorganic layer, an organic layer, and an inorganic layer that are sequentially laminated. The lamination structure of the thin film encapsulation layer (TFE) is not particularly limited.

A display area DM-DA and a non-display area DM-NDA are defined in the display module DM. The display area DM-DA and the non-display area DM-NDA of the display module DM correspond to the display area DA and the non-display area NDA of the display device DD (FIG. 2), respectively.

The pixel driver of the circuit layer DP-CL is disposed in the display area DM-DA. In addition, some of the signal lines SL1 to SLm, DL1 to DLn, EL1 to ELm, CSL1, CSL2, and PL, (see FIG. 8) of the circuit layer DP-CL are disposed in the display area DM-DA and the non-display area DM-NDA.

The light-emitting elements of the light-emitting element layer DP-OLED are disposed in the display area DM-DA. The thin film encapsulation layer TFE is disposed in the display area DM-DA and the non-display area DM-NDA. However, in an embodiment, it is sufficient for the thin film encapsulation layer TFE to cover the display area DM-DA and at least a portion of the non-display area DM-NDA, and it may not extend over the entire non-display area DM-NDA.

The input sensor ISP may include a plurality of electrodes that sense an external input, a plurality of trace lines that are connected to the plurality of electrodes, and an organic layer and/or an inorganic layer that insulates/protects the plurality of electrodes or the trace lines. The input sensor ISP may be a capacitive sensor, but is not particularly limited.

When the display module DM is manufactured, the input sensor ISP may be directly disposed on the thin film encapsulation layer TFE through continuous processes. That is, in an embodiment, a separate adhesion member is not disposed between the thin film encapsulation layer TFE and the input sensor ISP. However, the present disclosure is not limited thereto, and the input sensor ISP may be manufactured as a separate panel from the display module DM and attached to the display module DM by an adhesion layer.

The display module DM may further include a functional layer disposed on the electronic panel EP. The functional layer may be, for example, an anti-reflection layer or an impact absorption layer. The functional layer may be manufactured separately from the electronic panel EP, may be disposed on the electronic panel EP, and may be coupled to the electronic panel EP while including an adhesion member.

The display module DM-1 of FIG. 6B includes the electronic panel EP-1, which has a structure different from that of the electronic panel EP illustrated in FIG. 6A. Referring to FIG. 6B, the electronic panel EP-1 according to an embodiment may include an anti-reflection layer RPL. The anti-reflection layer RPL may be directly formed on the input sensor ISP when the display module DM-1 is manufactured.

The anti-reflection layer RPL may reduce a reflectance of external light that is input to the display device DD (see FIG. 5). The anti-reflection layer RPL may include an optical film that reduces the reflectance of external light. For example, the anti-reflection layer RPL may include a plurality of color filters and light-shielding patterns, or may include a reflection adjustment layer including pigments and/or dyes.

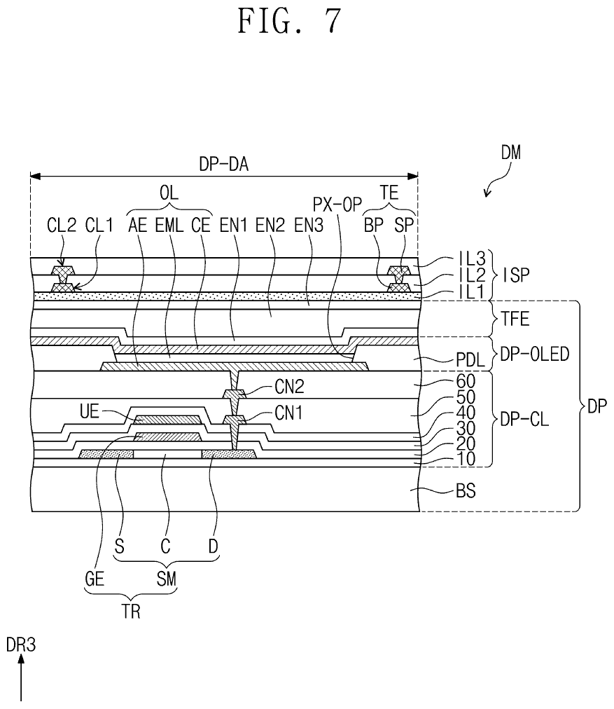

FIG. 7 is a cross-sectional view of a display module according to an embodiment of the present disclosure. For example, FIG. 7 illustrates a cross section of a pixel disposed in the display area DP-DA by way of example.

Referring to FIG. 7, the display module DM may include a display panel DP and an input sensor ISP disposed on the display panel DP. The above description may be equally applied to respective configurations described herein.

As described above with reference to FIG. 6A, the display panel DP may include a base layer BS, a circuit layer DP-CL disposed on the base layer BS, a light-emitting element layer DP-OLED disposed on the circuit layer DP-CL, and a thin film encapsulation layer TFE disposed on the light-emitting element layer DP-OLED.

The base layer BS has insulating properties and may provide a base surface on which components of the display module DM are disposed. The base layer BS may have flexibility to be bendable. For example, the base layer BS may be bent at a specific curvature.

The circuit layer DP-CL may include insulation layers 10, 20, 30, 40, 50, and 60 disposed on the base layer BS, a transistor TR of the pixel PX (see FIG. 8), an upper electrode UE, and connection electrodes CN1 and CN2. The insulation layers 10 to 60 may include first to sixth insulation layers 10 to 60 that are sequentially laminated in the thickness direction on the base layer BS. However, embodiments of the insulation layers 10 to 60 included in the circuit layer DP-CL are not limited thereto, and may be changed according to the configuration or manufacturing process of the circuit layer DP-CL.

The first insulation layer 10 may be disposed on the base layer BS. The first insulation layer 10 may be provided as a barrier layer and/or a buffer layer that may prevent foreign substances from being introduced into the display module DM. The first insulation layer 10 may improve a coupling force between the base layer BS, and the semiconductor pattern SM and/or the conductive pattern of the circuit layer DP-CL. The first insulation layer 10 may include at least any one of a silicon oxide layer and a silicon nitride layer. In an embodiment, the first insulation layer 10 may include silicon oxide layers and silicon nitride layers that are alternately laminated.

In an embodiment, the base layer BS and the first insulation layer 10 may extend across the display panel DP, including into the second area AA2 where the wiring interconnect and insulation structures are located. These layers may provide foundational mechanical support for wiring that connects to the bending area BA, as described further below.

The pixel PX (see FIG. 8) may be disposed on the base layer BS. The pixel PX (see FIG. 8) may be disposed to correspond to the display area DA. The pixel PX (see FIG. 8) may include a transistor TR and a light-emitting element OL.

The transistor TR may include a semiconductor pattern SM and a gate electrode GE. The semiconductor pattern SM may be disposed on the first insulation layer 10. The semiconductor pattern SM may include a channel C, a source S, and a drain D. The semiconductor pattern SM may include a silicon semiconductor, and may include, for example, a single crystal silicon semiconductor, a polysilicon semiconductor, or an amorphous silicon semiconductor. However, the present disclosure is not limited thereto, and the semiconductor pattern SM may include an oxide semiconductor. The semiconductor pattern SM according to an embodiment of the present disclosure may be formed of various materials as long as it has semiconductor properties, and is not limited to any one configuration.

The semiconductor pattern SM may include a plurality of areas having different electrical characteristics depending on whether they are doped or reduced. For example, the semiconductor pattern SM may include an area with a high conductivity due to doping or reduction of metal oxides, and the area with the high conductivity may serve as an electrode or signal wiring line of the transistor TR. This may correspond to the source S and the drain D of the transistor TR. The semiconductor pattern SM may include an area that is not doped and thus has a relatively low conductivity, and this may correspond to the channel C (or active region) of the transistor TR.

The second insulation layer 20 may be disposed on the first insulation layer 10 to cover the semiconductor pattern SM. The gate electrode GE may be disposed on the second insulation layer 20. The second insulation layer 20 may be disposed between the semiconductor pattern SM of the transistor TR and the gate electrode GE. The gate electrode GE may overlap the channel C of the semiconductor pattern SM on a plane. The gate electrode GE may function as a mask in a process of doping the semiconductor pattern SM. The gate electrode GE may include, for example, molybdenum (Mo) having heat resistance, an alloy containing molybdenum, titanium (Ti), an alloy containing titanium, and the like, but the present disclosure is not limited thereto.

The structure of the transistor TR illustrated in FIG. 7 is an example. In an embodiment, the source S or the drain D of the transistor TR may be electrodes formed independently from the semiconductor pattern SM. In this case, the source S and the drain D may contact the semiconductor pattern SM or may be connected to the semiconductor pattern SM through an insulation layer. Furthermore, the gate electrode GE may be disposed under the semiconductor pattern SM. The transistor TR according to an embodiment of the present disclosure may be formed in various structures, and the present disclosure is not limited to any particular embodiment.

The second insulation layer 20 and the third to sixth insulation layers 30 to 60 that will be described further below may include at least one of an inorganic layer and an organic layer. For example, the inorganic layer may include at least one of aluminum oxide, titanium oxide, silicon oxide, silicon oxynitride, zirconium oxide, and hafnium oxide. For example, the organic layer may include at least one of acrylate-based resin, methacrylate-based resin, polyisoprene, vinyl-based resin, epoxy-based resin, urethane-based resin, cellulose-based resin, siloxane-based resin, polyamide-based resin, and perylene-based resin.

The third insulation layer 30 is disposed on the second insulation layer 20, and may cover the gate electrode GE. The upper electrode UE may be disposed on the third insulation layer 30. The upper electrode UE may overlap the gate electrode GE on a plane, and the gate electrode GE and the upper electrode UE that overlap each other may form a capacitor.

The fourth insulation layer 40 is disposed on the third insulation layer 30, and may cover the upper electrode UE. The connection electrodes CN1 and CN2 may include a first connection electrode CN1 and a second connection electrode CN2. The first connection electrode CN1 may be disposed on the fourth insulation layer 40. The fifth insulation layer 50 may be disposed on the fourth insulation layer 40 to cover the first connection electrode CN1. The second connection electrode CN2 may be disposed on the fifth insulation layer 50. The sixth insulation layer 60 may be disposed on the fifth insulation layer 50 to cover the second connection electrode CN2. In an embodiment, at least any one of the fifth insulation layer 50 and the sixth insulation layer 60 may include an organic layer, and may provide a substantially flat upper surface while covering a step difference between components disposed below.

The first connection electrode CN1 may be electrically connected to the semiconductor pattern SM through a contact hole that passes through the second to fourth insulation layers 20 to 40. The second connection electrode CN2 may be electrically connected to the first connection electrode CN1 through a contact hole that passes through the fifth insulation layer 50.

Each of the first connection electrode CN1 and the second connection electrode CN2 may include a conductive material. Each of the first connection electrode CN1 and the second connection electrode CN2 may include, for example, gold, silver, copper, aluminum, platinum, molybdenum, titanium, and alloys thereof. At least any one of the first connection electrode CN1 and the second connection electrode CN2 may include conductive layers having a multilayer structure. For example, at least any one of the first connection electrode CN1 and the second connection electrode CN2 may have a three-layer structure of titanium/aluminum/titanium. However, embodiments are not limited thereto.

According to an embodiment of the circuit layer DP-CL, at least any one of the first connection electrode CN1 and the second connection electrode CN2 may be omitted. According to an embodiment of the circuit layer DP-CL, an additional connection electrode that connects the transistor TR and the light-emitting element OL may be further disposed. The electrical connection method of the light-emitting element OL and the transistor TR may be variously changed according to the numbers of insulation layers disposed between the light-emitting element OL and the transistor TR, and the present disclosure is not limited to any particular embodiment.

The light-emitting element layer DP-OL may include a light-emitting element OL and a pixel definition film PDL. The light-emitting element OL and the pixel definition film PDL may be disposed on the sixth insulation layer 60. The light-emitting element OL may include a first electrode AE, a light emission layer EML, and a second electrode CE.

The first electrode AE may be electrically connected to the second connection electrode CN2 through a contact hole that passes through the sixth insulation layer 60. The first electrode AE may be electrically connected to the transistor TR through the first and second connection electrodes CN1 and CN2.

In the pixel definition film PDL, a pixel opening PX-OP that exposes at least a portion of the first electrode AE may be defined. An area of the first electrode AE, which is exposed from the pixel definition film PDL, may correspond to a light emitting area. The pixel definition film PDL may include, for example, an inorganic layer, an organic layer, or a composite material layer. According to an embodiment, the pixel definition film PDL may further include a black pigment or a black dye.

The light emission layer EML may be disposed on the first electrode AE. The light emission layer EML may provide a specific color light. The light emission layer EML may be disposed in correspondence to the pixel opening PX-OP defined in the pixel definition film PDL. A plurality of light-emitting elements OL and pixel openings PX-OP may be provided, and the light emission layers EM of the light-emitting elements OL may be disposed in correspondence to the pixel openings PX-OP, respectively, and may be provided in the form of patterns that are spaced apart from each other. However, the present disclosure is not limited thereto, and the light emission layers EM of the light-emitting elements OL may be formed as an integral common layer.

The second electrode CE may be disposed on the light emission layer EML and the pixel definition film PDL. The second electrode CE may be provided as a common electrode that is commonly disposed in the pixels PX (see FIG. 8).

The light-emitting element OL may further include at least any one of a hole control area disposed between the first electrode AE and the light emission layer EML and an electronic control area disposed between the light emission layer EML and the second electrode CE. The hole control area may include at least any one of a hole generation layer, a hole transport layer, and an electron blocking layer, and the electron control area may include at least any one of an electron generation layer, an electron transport layer, and a hole blocking layer.

In an embodiment, the same or similar organic material used for the pixel definition film PDL may also be employed to form a first organic insulation layer OIL1, which is described further below. This shared material base may simplify fabrication and improve uniformity of mechanical response across the folding area.

The thin film encapsulation layer TFE may be disposed on the light-emitting element layer DP-OL. The thin film encapsulation layer TFE may be disposed on the light-emitting element OL and the pixel definition film PDL, and may seal the light-emitting element OL. The thin film encapsulation layer TFE may include at least any one of an inorganic layer and an organic layer. In an embodiment, the thin film encapsulation layer TFE may include a first inorganic layer EN1, a second inorganic layer EN3, and an organic layer EN2 disposed between the first and second inorganic layers EN1 and EN3. However, the configuration of the thin film encapsulation layer TFE is not limited thereto as long as the light-emitting element OL may be sealed.

The first inorganic layer EN1 may be disposed on the second electrode CE, and the organic layer EN2 and the second inorganic layer EN3 may be sequentially disposed on the first inorganic layer EN1 in a thickness direction of the display panel DP. The first and second inorganic layers EN1 and EN3 may protect the light-emitting element OL from, for example, moisture or oxygen that may be introduced into the display module DM. For example, each of the first and second inorganic layers EN1 and EN3 may include at least any one of silicon nitride, silicon oxynitride, silicon oxide, titanium oxide, and aluminum oxide. However, the material of the first and second inorganic layers EN1 and EN3 is not limited to the above example. The organic layer EN2 may prevent foreign substances from being introduced into the light-emitting element OL, and may cover a step difference of the components disposed under the organic layer EN2. For example, the organic layer EN2 may include an acrylic organic material. However, the material of the organic layer EN2 is not limited to the above example.

The input sensor ISP may be disposed on the display panel DP. The input sensor ISP may include a first sensing insulation layer IL1, a second sensing insulation layer IL2, a third sensing insulation layer IL3, a first sensing conductive layer CL1, and a second sensing conductive layer CL2. The above description may be equally applied to respective configurations described herein.

The first sensing insulation layer IL1 may contact an uppermost layer of the thin film encapsulation layer TFE. For example, the first sensing insulation layer IL1 may contact the second inorganic layer EN3 of the thin film encapsulation layer TFE. The first sensing insulation layer IL1 of the input sensor ISP may be directly formed on a base surface that is provided by the thin film encapsulation layer TFE. However, the present disclosure is not limited thereto. For example, in an embodiment, the first sensing insulation layer IL1 may be omitted, and in this case, the first sensing conductive layer CL1 of the input sensor ISP may contact the thin film encapsulation layer TFE.

The first sensing conductive layer CL1 may be disposed on the first sensing insulation layer IL1, and the second sensing conductive layer CL2 may be disposed on the second sensing insulation layer IL2. The third sensing insulation layer IL3 may be disposed on the second sensing insulation layer IL2 to cover the second sensing conductive layer CL2. Each of the first sensing insulation layer IL1 and the second sensing insulation layer IL2 may include silicon nitride. The third sensing insulation layer IL3 may include a substantially flat upper surface. The third sensing insulation layer IL3 may include an organic material.

The first sensing conductive layer CL1 and the second sensing conductive layer CL2 may constitute a sensing electrode TE. For example, the first sensing conductive layer CL1 may include a connection pattern BP of the sensing electrode TE, and the second sensing conductive layer CL2 may include a sensing pattern SP of the sensing electrode TE. However, the present disclosure is not limited thereto, and the first sensing conductive layer CL1 may include a sensing pattern SP, and the second sensing conductive layer CL2 may include a connection pattern BP in an embodiment.

The connection pattern BP may be disposed on a layer that is different from the sensing pattern SP and may be connected through a contact hole that passes through the second sensing insulation layer IL2. However, the present disclosure is not limited thereto, and the connection pattern BP and the sensing pattern SP may be disposed on the same layer and be formed integrally.

The sensing electrode TE may be a mesh-shaped pattern, and may be disposed in correspondence to an area in which the pixel definition film PDL is disposed. However, the present disclosure is not limited thereto. For example, in an embodiment, the sensing electrode TE may be provided in a single-shaped pattern that overlaps the light-emitting element OL, and in this case, the sensing electrode TE may include a transparent conductive material.

FIG. 8 is a plan view of a display panel according to an embodiment of the present disclosure.

Referring to FIG. 8, the display panel DP may include a display area DP-DA and a non-display area DP-NDA around the display area DP-DA. The display area DP-DA and the non-display area DP-NDA are distinguished depending on the arrangement of the pixels PX. The display area DP-DA and the non-display area DP-NDA correspond to the display area DA and the non-display area NDA of the electronic device ED (FIG. 2), respectively. A scan driver SDV, a data driver DDV, and an emission driver EDV may be disposed in the non-display area DP-NDA.

The display panel DP includes a first area AA1, a second area AA2, and a bending area BA, which are separated from each other in the second direction DR2. While the electronic device ED is unfolded as illustrated in FIG. 2, the first area AA1 and the second area AA2 of the display panel DP mounted on the electronic device ED are disposed on different planes. The bending area BA is disposed between the first area AA1 and the second area AA2. The bending area BA may be bent around a bending axis that extends in the second direction DR2.

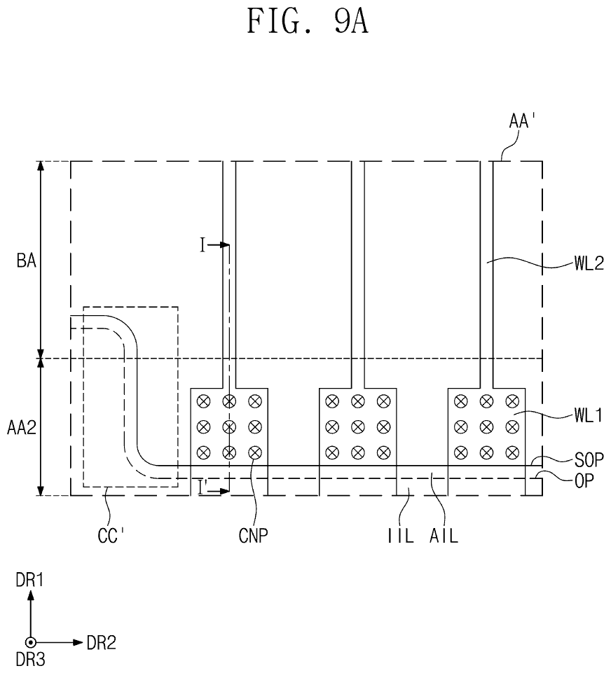

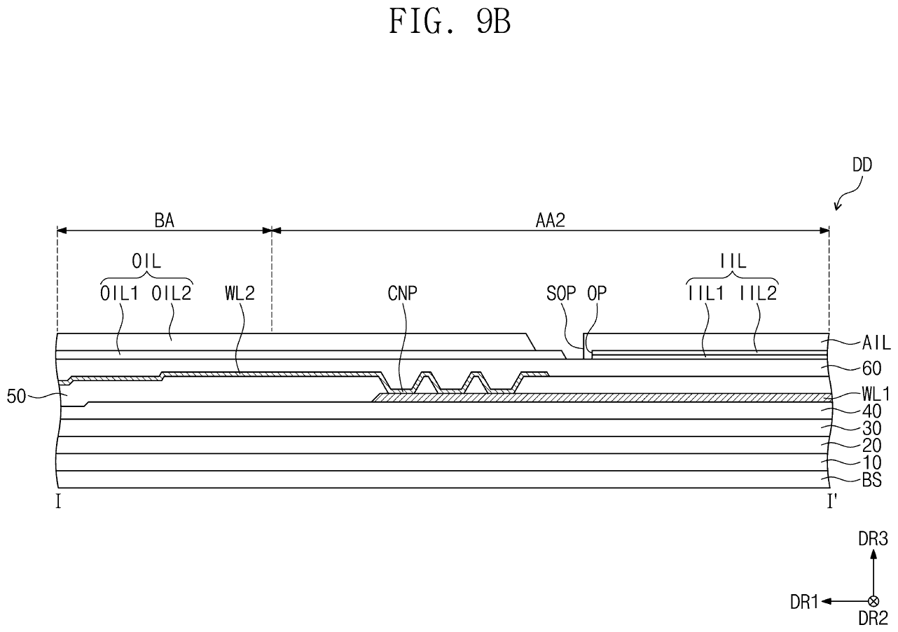

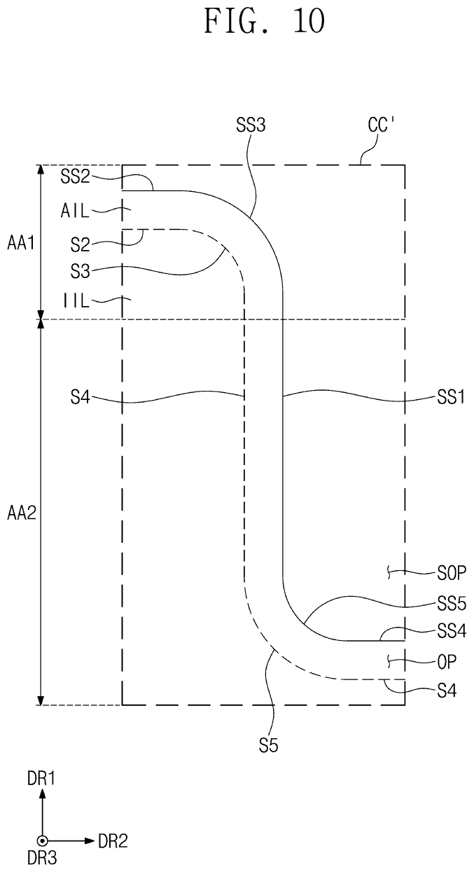

As shown in FIG. 8, in an embodiment, the data lines DL1 to DLn and the power line PL may extend across the first area AA1, the bending area BA, and the second area AA2. For example, connection structures formed in the second area AA2 near the interface with the bending area BA may be subject to mechanical stress during panel folding. To address this, the structural layout of the wiring interconnects and insulation layers, such as the configuration of contact parts and the shape of openings in the inorganic insulation layer, may be adapted to reduce the effects of repeated bending. Related structures will be described in further detail below with reference to FIGS. 9A and 9B.

The first area AA1 is an area corresponding to the display surface DS (see FIG. 2). The first area AA1 may include a first non-folding area NFA10, a second non-folding area NFA20, and a folding area FA1. The first non-folding area NFA10, the second non-folding area NFA20, and the folding area FA1 correspond to the first non-folding area NFA1, the second non-folding area NFA2, and the folding area FA of FIGS. 2 to 4, respectively.

The lengths of the bending area BA and the second area AA2 in the first direction DR1 may be smaller than the length of the first area AA1. The second area AA2 and the bending area BA may be partial areas of the non-display area DP-NDA.

The display panel DP may include a plurality of pixels PX, a plurality of scan lines SL1 to SLm, a plurality of data lines DL1 to DLn, a plurality of light emission lines EL1 to ELm, first and second control lines CSL1 and CSL2, a power line PL, and a plurality of pads PD. Here, m and n are positive integers. The pixels PX may be connected to the scan lines SL1 to SLm, the data lines DL1 to DLn, and the light emission lines EL1 to ELm.

The data driver DDV may be disposed in the second area AA2. The data driver DDV may be an integrated circuit chip. The scan lines SL1 to SLm may extend in the first direction DR1 to be connected to the scan driver SDV. The data lines DL1 to DLn may extend in the first direction DR1 and may be connected to the data driver DDV via the bending area BA. The light emission lines EL1 to ELm may extend in the second direction DR2 to be connected to the emission driver EDV.

The power line PL may extend in the first direction DR1 and may extend from the first area AA1 to the second area AA2 via the bending area BA. The power line PL may provide a driving voltage to the pixels PX. The power line PL may be disposed in the non-display area DP-NDA. The power line PL may extend in the first direction DR1 and may be disposed in the non-display area NDA. Although it is illustrated that the power line PL is disposed between the display area DA and the emission driver EDV, the present disclosure is not limited thereto. For example, in an embodiment, the power line PL may be disposed between the display area DA and the scan driver SDV.

The connection lines CNL may extend in the second direction DR2 and may be arranged in the first direction DR1. The connection lines CNL may be connected to the power line PL and the pixels PX. The driving voltage may be applied to the pixels PX through the power lines PL and the connection lines CNL connected to each other.

The first control line CSL1 may be connected to the scan driver SDV, and may extend toward a lower end of the second area AA2 via the bending area BA. The second control line CSL2 may be connected to the emission driver EDV, and may extend toward a lower end of the second area AA2 via the bending area BA.

When viewed on a plane, pads PD may be disposed adjacent to a lower end of the second area AA2. The data driver DDV, the power line PL, the first control line CSL1, and the second control line CSL2 may be connected to the pads PD. The data lines DL1 to DLn may be connected to corresponding pads PD through the data driver DDV. For example, the data lines DL1 to DLn may be connected to the data driver DDV, and the data driver DDV may be connected to pads PD corresponding to the data lines DL1 to DLn, respectively.

A printed circuit board may be connected to the pads PD, and a timing controller and a voltage generator may be disposed on the printed circuit board. The timing controller may be manufactured as an integrated circuit chip and may be mounted on the printed circuit board. The timing controller and the voltage generator may be connected to the pads PD through the printed circuit board. The timing controller may control operations of the scan driver SDV, the data driver DDV, and the emission driver EDV. The timing controller may generate a scan control signal, a data control signal, and a light emission control signal in response to control signals received from an external source. The scan control signal may be provided to the scan driver SDV through a first control line CSL1. The light emission control signal may be provided to the emission driver EDV through the second control line CSL2. The data control signal may be provided to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. Data voltages may be applied to the pixels PX through data lines DL1 to DLn.

The emission driver EDV may generate a plurality of light emission signals in response to the light emission control signal. The light emission signals may be applied to the pixels PX through the light emission lines EL1 to ELm.

The pixels PX may receive data voltages in response to the scan signals. The pixels PX may display an image by emitting light of luminance corresponding to the data voltages in response to the emission signals. The emission time of the pixels PX may be controlled by the emission signals.

FIG. 9A is an enlarged view of a portion of a display panel according to an embodiment of the present disclosure. FIG. 9B is a cross-sectional view of a display device according to an embodiment of the present disclosure. For example, FIG. 9A is an enlarged view of area AA′ area illustrated in FIG. 8, and FIG. 9B is a cross-sectional view of the display device DD according to an embodiment, taken along line I-I′ of FIG. 9A. Hereinafter, for convenience of explanation, a further description of components and technical aspects previously described will be omitted.

Referring to FIG. 9A, a first wiring line WL1 may be disposed in the second area AA2, and a second wiring line WL2 may be disposed in the bending area BA. The first wiring line WL1 and the second wiring line WL2 may be portions that extend from the signal lines SL1 to SLm, DL1 to DLn, CSL1, CSL2, and PL illustrated in FIG. 8. A plurality of first wiring lines WL1 and a plurality of second wiring lines WL2 may be provided, respectively. The first wiring lines WL1 and the second wiring lines WL2 may extend in the first direction DR1, and may be arranged in the second direction DR2. The first wiring line WL1 may be referred to as a signal wiring line, and the second wiring line WL2 may be referred to as a connection wiring line.

Referring to FIGS. 9A and 9B, the base layer BS and the first to sixth insulation layers 10 to 60 may extend to the bending area BA and the second area AA2. For convenience of explanation, a further description of the base layer BS and the first to sixth insulation layers 10 to 60, which were previously described, will be omitted.

The first wiring line WL1 may be disposed on the fourth insulation layer 40, and may overlap the second area AA2. The first wiring line WL1 may be disposed on the same layer as the first connection electrode CN1 illustrated in FIG. 7. That is, the first wiring line WL1 may be formed through the same process as that of the first connection electrode CN1. The fifth insulation layer 50 may cover the first wiring line WL1. However, the present disclosure is not limited thereto. For example, the first wiring line WL1 may be disposed on the same layer as the gate electrode GE illustrated in FIG. 7.

The second wiring line WL2 may extend from the second area AA2 in the first direction DR1. That is, the second wiring line WL2 may extend from the second area AA2 to the bending area BA. The second wiring line WL2 may overlap the bending area BA. The second wiring line WL2 may be disposed on the first wiring line WL1. For example, the second wiring line WL2 may be disposed on the fifth insulation layer 50. The second wiring line WL2 may be disposed on the same layer as the second connection electrode CN2. That is, the second wiring line WL2 may be formed through the same process as that of the second connection electrode CN2. The second wiring line WL2 may be covered by the sixth insulation layer 60. However, the present disclosure is not limited thereto. For example, in an embodiment, the second wiring line WL2 may be disposed on the same layer as the gate electrode GE illustrated in FIG. 7.

The first wiring line WL1 and the second wiring line WL2 may be electrically connected to each other. For example, the first wiring line WL1 and the second wiring line WL2 may be electrically connected to each other through a contact part CNP. The contact part CNP may be defined as a part in which the second wiring line WL2 passes through the fifth insulation layer 50 and contacts the first wiring line WL1. The contact part CNP may be disposed in the second area AA2. A plurality of contact parts CNP may be provided. Although the number of contact parts CNP in one first wiring line WL1 is illustrated as nine in FIG. 9A, the present disclosure is not limited thereto. For example, the number of contact parts CNP in one first wiring line WL1 may be provided as a single number or may be provided as ten or more.

In an embodiment, the region including the contact part CNP may be disposed adjacent to the bending area BA and may be subject to mechanical strain when the display device is folded. Since the contact part CNP electrically connects stacked wiring lines WL1 and WL2, mechanical stress near this interface may adversely affect electrical continuity or lead to physical damage if not properly managed. Accordingly, the material stacking and insulation structure in this area are configured in the spatial configuration disclosed herein, which may maintain reliability under repeated bending.

The organic insulation layer OIL may be disposed on the second wiring line WL2. For example, the organic insulation layer OIL may be disposed on the sixth insulation layer 60. The organic insulation layer OIL may entirely overlap the second wiring line WL2. Furthermore, on a plane, the organic insulation layer OIL may cover the second wiring line WL2, and may cover one end of the first wiring line WL1. One end of the first wiring line WL1, which overlaps the organic insulation layer OIL, may be adjacent to the bending area BA.

The organic insulation layer OIL may include a first organic insulation layer OIL1 and a second organic insulation layer OIL2. The first organic insulation layer OIL1 may be disposed on the sixth insulation layer 60. The second organic insulation layer OIL2 may be disposed on the first organic insulation layer OIL1, and may entirely overlap the first organic insulation layer OIL1. According to an embodiment of the present disclosure, the length of the first organic insulation layer OIL1 in the first direction DR1 may be greater than the length of the second organic insulation layer OIL2 in the first direction DR1. That is, the second organic insulation layer OIL2 may expose one end of the first organic insulation layer OIL1.

The first organic insulation layer OIL1 may include the same material as that of the pixel definition film PDL illustrated in FIG. 7. That is, the first organic insulation layer OIL1 may be formed through the same process as that of the pixel definition film PDL illustrated in FIG. 7. The second organic insulation layer OIL2 may include the same material as that of the spacer disposed on the pixel definition film PDL illustrated in FIG. 7. That is, the second organic insulation layer OIL2 may be formed simultaneously with the spacer. In an embodiment, the first organic insulation layer OIL1 and the second organic insulation layer OIL2 may include the same material. For example, the first organic insulation layer OIL1 and the second organic insulation layer OIL2 may be formed substantially simultaneously.

According to an embodiment of the present disclosure, an inorganic insulation layer IIL may be disposed on the first wiring line WL1. For example, the inorganic insulation layer IIL may be disposed on the sixth insulation layer 60. In the inorganic insulation layer IIL, an opening OP that overlaps the organic insulation layer OIL may be defined. The opening OP may entirely overlap the bending area BA. For example, the opening OP may overlap an entirety of the bending area BA. The opening OP may overlap the contact part CNP. The opening OP may extend in the second direction DR2. The inorganic insulation layer IIL may be spaced apart from the organic insulation layer OIL in the first direction DR1. However, the present disclosure is not limited thereto, and one end of the organic insulation layer OIL may be covered by the inorganic insulation layer IIL in an embodiment.

In an embodiment, the opening OP defined in the inorganic insulation layer IIL may be configured to reduce internal stress concentrations by modifying the stiffness distribution near the contact part CNP. For example, the shape of the opening OP may include a curved boundary portion which can limit abrupt transitions in the mechanical modulus across the insulation interface. This configuration may help reduce the likelihood of localized crack formation or delamination in the inorganic insulation layer IIL when the adjacent region undergoes deformation during bending.

The inorganic insulation layer IIL may include a first sub insulation layer IIL1 and a second sub insulation layer IIL2. The second sub insulation layer IIL2 may be disposed on the first sub insulation layer IIL1. The first sub insulation layer IIL1 may include the same material as that of the first sensing insulation layer IL1 illustrated in FIG. 7. That is, the first sub insulation layer IIL1 may be formed through the same process as that of the first sensing insulation layer IL1. The second sub insulation layer IIL2 may include the same material as that of the second sensing insulation layer IL2 illustrated in FIG. 7. That is, the second sub insulation layer IIL2 may be formed through the same process as that of the second sensing insulation layer IL2.

In an embodiment, the first sub insulation layer IIL1 and the second sub insulation layer IIL2 may include the same material. For example, each of the first sub insulation layer IIL1 and the second sub insulation layer IIL2 may include silicon nitride. The first sub insulation layer IIL1 may be formed by the same process as that of the second sub insulation layer IIL2. That is, the first sub insulation layer IIL1 and the second sub insulation layer IIL2 may be patterned with the same mask at once.

An auxiliary insulation layer AIL may be disposed on the inorganic insulation layer IIL. The auxiliary insulation layer AIL may entirely overlap the inorganic insulation layer IIL. The auxiliary insulation layer AIL may cover one end of the inorganic insulation layer IIL. The auxiliary insulation layer AIL may include an organic material. The auxiliary insulation layer AIL may include the same material as that of the third sensing insulation layer IL3 illustrated in FIG. 7. That is, the auxiliary insulation layer AIL may be formed through the same process as that of the third sensing insulation layer IL3. In the auxiliary insulation layer AIL, a sub opening SOP that overlaps the organic insulation layer OIL may be defined. The sub-opening SOP may entirely overlap the bending area BA. The sub opening SOP may overlap the contact part CNP. The sub opening SOP may extend in the second direction DR2. The sub opening SOP may overlap the opening OP on a plane. The size of the sub opening SOP on the plane (e.g., in a plan view) may be smaller than the size of the opening OP on the plane (e.g., in the plan view).

The organic insulation layer OIL according to an embodiment of the present disclosure may cover ends of the first wiring line WL1 and the second wiring line WL2, which may prevent damage to the first wiring line WL1 and the second wiring line WL2 due to the inorganic insulation layer IIL. For example, hydrogen radicals and ammonia gases may be generated due to the oxidation of the inorganic insulation layer IIL. In this case, when distances between one end of the inorganic insulation layer IIL, and the first wiring line WL1 and the second wiring line WL2 are short, hydrogen radicals and ammonia gases may easily reach the first wiring line WL1 and the second wiring line WL2. The organic insulation layer OIL according to embodiments of the present disclosure may cover ends of the first wiring line WL1 and the second wiring line WL2, and as a result, damage to the first wiring line WL1 and the second wiring line WL2 due to hydrogen radicals and ammonia gas may be prevented or reduced.

According to embodiments, in combination with the stress-dispersing effects of the opening geometry, the organic insulation layer OIL may also contribute to the physical and chemical protection of the contact part CNP. By covering the ends of the first and second wiring lines WL1 and WL2, the organic insulation layer OIL may reduce the direct exposure of the metal wiring to reactive species such as, for example, hydrogen radicals and ammonia generated during encapsulation or environmental ingress. This may help prevent corrosion or deterioration of contact resistance over time.

FIG. 10 is an enlarged view of area CC′ illustrated in FIG. 9A.

Referring to FIG. 10, the inorganic insulation layer IIL may include first to fifth sides S1, S2, S3, S4, and S5 that define the opening OP. The first to fifth sides S1, S2, S3, S4, and S5 may correspond to a side surface of an inorganic insulation layer IIL, which defines the opening OP illustrated in FIG. 9B.

The first side surface S1 may extend in the first direction DR1. Each of the second side surface S2 and the fourth side surface S4 may extend in the second direction DR2. According to an embodiment of the present disclosure, the third side surface S3 that connects the first side surface S1 and the second side surface S2 and the fifth side surface S5 that connects the first side surface S1 and the fourth side surface S4 may include a curved surface. The curved surfaces of the third side surface S3 and the fifth side surface S5 may have a shape when viewed on a plane.

The auxiliary insulation layer AIL may include first to fifth auxiliary side surfaces SS1, SS2, SS3, SS4, and SS5. The first to fifth auxiliary side surfaces SS1, SS2, SS3, SS4, and SS5 may correspond to a side surface of an auxiliary insulation layer AIL, which defines the sub opening SOP illustrated in FIG. 9B.

The first auxiliary side surface SS1 may extend in the first direction DR1. Each of the second auxiliary side surface SS2 and the fourth auxiliary side surface SS4 may extend in the second direction DR2. According to an embodiment of the present disclosure, the third auxiliary side surface SS3 that connects the first auxiliary side surface SS1 and the second auxiliary side surface SS2, and the fifth auxiliary side surface SS5 that connects the first auxiliary side surface SS1 and the fourth auxiliary side surface SS4, may include a curved surface. The curved surfaces of the third auxiliary side surface SS3 and the fifth auxiliary side surface SS5 may have a shape when viewed on a plane. Each of the first to fifth auxiliary side surfaces SS1, SS2, SS3, SS4, and SS5 may be formed in parallel in correspondence to the first to fifth side surfaces S1, S2, S3, S4, and S5, respectively. However, the present disclosure is not limited thereto, and the first to fifth auxiliary side surfaces SS1, SS2, SS3, SS4, and SS5 may extend in the second direction DR2 without corresponding to the first to fifth side surfaces S1, S2, S3, S4, and S5 in an embodiment.

In an embodiment, the auxiliary side surfaces SS1 to SS5 of the auxiliary insulation layer AIL and the side surfaces S1 to S5 of the inorganic insulation layer IIL may be shaped and aligned such that the combined sub opening SOP and opening OP form a continuous cutout region in the stacked insulation structure. This continuous cutout may allow localized bending deformation to occur with reduced mechanical resistance, which may aid in reducing stress concentration near the contact region CNP.

Referring to FIGS. 7 and 9A to 10, when the display panel DP according to an embodiment of the present disclosure is bent, the inorganic insulation layer IIL that is adjacent to the bending area BA may be subjected to compressive stress, and thus, cracks may be generated in the inorganic insulation layer IIL. For example, cracks may be generated due to the compressive stress at a corner portion of the inorganic insulation layer IIL. However, because the third side surface S3 and the fifth side surface S5 of the inorganic insulation layer IIL, which correspond to the corner portion of the inorganic insulation layer IIL, include curved surfaces, it is possible to distribute the stress applied to the inorganic insulation layer IIL when the display panel DP is bent to prevent cracks from being generated in the inorganic insulation layer IIL. For example, when the display panel DP is bent, compressive stress may be applied to the inorganic insulation layer IIL disposed adjacent to the bending area BA. If this stress accumulates near corner portions of the opening OP, cracks may develop in the inorganic insulation layer IIL due to the brittle nature of inorganic materials. However, in an embodiment, the third side surface S3 and fifth side surface S5 of the opening OP may include curved shapes, which may reduce abrupt geometric transitions and help disperse stress across a broader area. This configuration may reduce peak stress values at corner points and suppress crack formation in the IIL during repeated bending.

The first side surface S1 may be spaced apart from the first wiring line WL1 and the second wiring line WL2 in the second direction DR2. As a result, when the display panel DP according to an embodiment of the present disclosure is bent, the inorganic insulation layer IIL is spaced apart from the first wiring line WL1 and the second wiring line WL2 on a plane even when the inorganic insulation layer IIL is subjected to compressive stress. As a result, the stress applied to the first wiring line WL1 and the second wiring line WL2 from the inorganic insulation layer IIL may be reduced.

In an embodiment, in addition to the curved geometry, the spatial offset of the first side surface S1 from the wiring lines WL1 and WL2 in the second direction DR2 may further reduce the transfer of mechanical stress. Because the opening OP does not directly overlap the ends of the wiring lines on a plane, the deformation of the inorganic insulation layer IIL under bending is less likely to induce strain at the contact points. This may contribute to improved reliability of electrical connections by reducing the likelihood of mechanical damage or delamination near the contact part CNP.

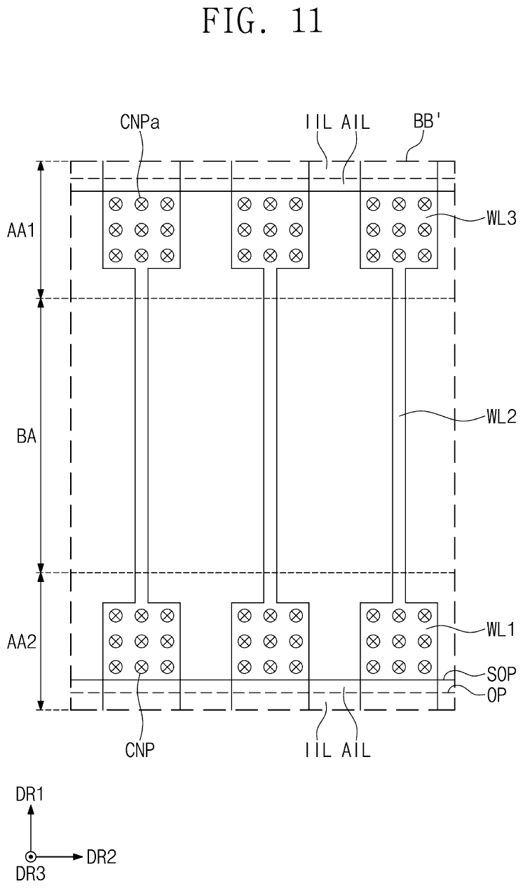

FIG. 11 is an enlarged view of a portion of a display panel according to an embodiment of the present disclosure. For example, FIG. 11 is an enlarged view of area BB′ illustrated in FIG. 8.

Referring to FIG. 11, a third wiring line WL3 may be further disposed in the first area AA1. The third wiring line WL3 may be a portion that extends from the signal lines SL1 to SLm, DL1 to DLn, CSL1, CSL2, and PL illustrated in FIG. 8. A plurality of third wiring lines WL3 may be provided. The third wiring lines WL3 may extend in the first direction DR1, and may be arranged in the second direction DR2. The third wiring lines WL3 may be referred to as signal lines. The third wiring lines WL3 may be disposed on the same layer as the first wiring line WL1.

The third wiring line WL3 and the second wiring line WL2 may be electrically connected to each other. For example, the third wiring line WL3 and the second wiring line WL2 may be electrically connected to each other through a contact part CNPa. Although the number of contact parts CNPa in one third wiring line WL3 is illustrated as nine in FIG. 11, the present disclosure is not limited thereto. For example, the number of contact parts CNPa in one third wiring line WL3 may be provided in a single number or may be provided in ten or more according to embodiments.

According to an embodiment of the present disclosure, the inorganic insulation layer IIL may be disposed on the third wiring line WL3. For example, the inorganic insulation layer IIL may be disposed on the sixth insulation layer 60 (see FIG. 9B). The opening OP defined in the inorganic insulation layer IIL may overlap one end of the third wiring line WL3. The description for the third wiring line WL3 may be substantially equally applied to the description for the first wiring line WL1, and thus, a further description thereof is omitted.

In an embodiment, the structural layout around the third wiring line WL3 and the contact part CNPa may be configured in a manner similar to that of the first wiring line WL1 and the contact part CNP. For example, the opening OP defined in the inorganic insulation layer IIL may include side surfaces having a curved profile, and may be spaced apart from the wiring lines in the second direction DR2. This arrangement may help disperse stress and reduce crack formation at the upper end of the second wiring line WL2 in a similar manner as described with reference to FIG. 10.

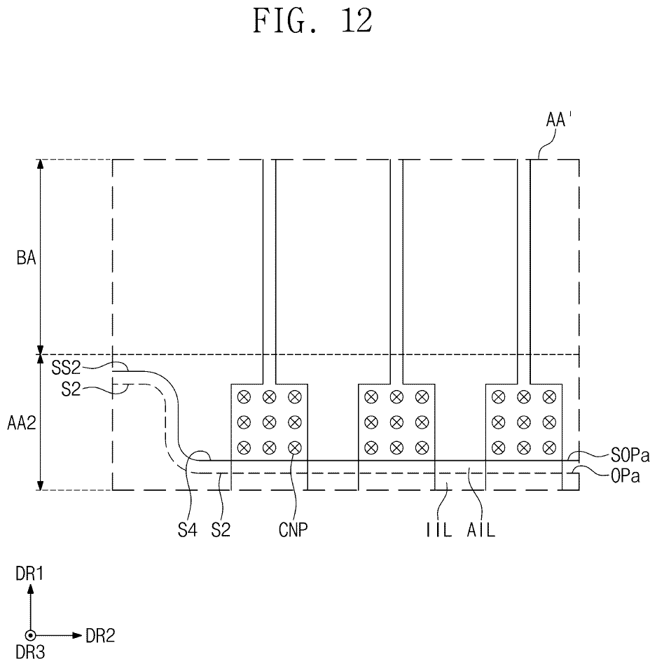

FIG. 12 is an enlarged view of a portion of a display panel according to an embodiment of the present disclosure. For example, FIG. 12 is an enlarged view of the area AA′ illustrated in FIG. 8 according to an embodiment.

Referring to FIG. 12, an opening OPa may be defined in an inorganic insulation layer IIL, and a sub opening SOPa may be defined in an auxiliary insulation layer AIL. Each of the opening OPa and the sub opening SOPa may completely overlap the bending area BA.

According to an embodiment of the present disclosure, the second side surface S2 and the fourth side surface S4 of the inorganic insulation layer IIL may be spaced apart from the bending area BA in the first direction DR1 on a plane, respectively. For example, the second side surface S2 of the inorganic insulation layer IIL, which is adjacent to the bending area BA, may be spaced apart from the bending area BA in the first direction DR1 on a plane. Furthermore, the second auxiliary side surface SS2 and the fourth auxiliary side surface SS4 of the auxiliary insulation layer AIL may be spaced apart from each other in the first direction DR1 on the bending area BA and a plane, respectively. For example, the second auxiliary side surface SS2 of the auxiliary insulation layer AIL, which is adjacent to the bending area BA, may be spaced apart from the bending area BA in the first direction DR1 on a plane. As a result, when the display panel DP (see FIG. 8) according to an embodiment of the present disclosure is bent, it is possible to reduce compressive stress in the inorganic insulation layer IIL that is adjacent to the bending area BA.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Each block, unit and/or module may be implemented by dedicated hardware, or as a combination of dedicated hardware to perform some functions and a processor (e.g., one or more programmed microprocessors and associated circuitry) to perform other functions.

When the display panel according to embodiments of the present disclosure is bent, the inorganic insulation layer that is adjacent to the bending area may be subjected to compressive stress, and thus, cracks may be generated in the inorganic insulation layer. Because the side surface of the inorganic insulation layer corresponding to the corner of the inorganic insulation layer includes a curved surface, it is possible to prevent cracks from being generated in the inorganic insulation layer by dispersing the stress received by the inorganic insulation layer, or to reduce the amount of cracks.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a base layer including a first area including a display area, a second area spaced apart from the first area in a first direction, and a bending area disposed between the first area and the second area;
a first wiring line overlapping the second area and extending in the first direction;
a second wiring line overlapping the bending area and electrically connected to the first wiring line; and
an inorganic insulation layer disposed on the first wiring line, and in which an opening overlapping a contact part, in which the first wiring line and the second wiring line are connected to each other, is defined,
wherein the inorganic insulation layer includes:
a first side surface extending in the first direction;
a second side surface extending in a second direction crossing the first direction; and
a third side surface connecting the first side surface and the second side surface, and having a curved shape in a plan view,
wherein the opening is defined by the first to third side surfaces.

2. The display device of claim 1, further comprising:
an auxiliary insulation layer disposed on the inorganic insulation layer and covering the inorganic insulation layer.

3. The display device of claim 2, further comprising:
a sub opening defined in the auxiliary insulation layer,
wherein the sub opening overlaps the contact part.

4. The display device of claim 3, wherein the auxiliary insulation layer includes:
a first auxiliary side surface extending in the first direction;
a second auxiliary side surface extending in the second direction; and
a third auxiliary side surface connecting the first auxiliary side surface and the second auxiliary side surface, and having the curved shape in the plan view,
wherein the sub opening is defined by the first to third auxiliary side surfaces.

5. The display device of claim 4, wherein
the first auxiliary side surface is parallel to the first side surface,
the second auxiliary side surface is parallel to the second side surface, and
the third auxiliary side surface is parallel to the third side surface.

6. The display device of claim 3, wherein
the sub opening overlaps the opening in the plan view, and
a size of the sub opening is smaller than a size of the opening in a plan view.

7. The display device of claim 1, further comprising:
an organic insulation layer disposed on the first wiring line,
wherein the organic insulation layer overlaps the opening, and
the organic insulation layer covers an end of the first wiring line and an end of the second wiring line.

8. The display device of claim 1, wherein the inorganic insulation layer further includes:
a fourth side surface extending in an opposite direction to the second direction; and
a fifth side surface connecting the first side surface and the fourth side surface, and including a curved surface.

9. The display device of claim 8, wherein the second side surface and the fourth side surface are spaced apart from the bending area in the first direction.

10. The display device of claim 1, wherein
the first side surface is spaced apart from the contact part in the second direction in the plan view.

11. The display device of claim 1, wherein
the opening overlaps an entirety of the bending area.

12. The display device of claim 1, further comprising:
a third wiring line disposed in the first area and electrically connected to the second wiring line,
wherein the inorganic insulation layer is disposed on the third wiring line, and
one end of the third wiring line overlaps the opening.

13. A display device, comprising:
a base layer including a first area, a second area spaced apart from the first area in a first direction, and a bending area disposed between the first area and the second area;
a first wiring line overlapping the second area and extending in the first direction;
a second wiring line overlapping the bending area and electrically connected to the first wiring line; and
an inorganic insulation layer disposed on the first wiring line, and in which an opening overlapping the bending area is defined,
wherein the inorganic insulation layer includes:
a first side surface extending in the first direction; and
a second side surface extending in a second direction crossing the first direction,
wherein the second side surface is spaced apart from the bending area in the first direction in a plan view.

14. The display device of claim 13, wherein
the inorganic insulation layer further includes a third side surface connecting the first side surface and the second side surface, and having a curved shape in the plan view,
wherein the opening is defined by the first to third side surfaces.

15. The display device of claim 13, wherein
the opening overlaps a contact part in which the first wiring line and the second wiring line are electrically connected to each other.

16. The display device of claim 15, wherein
the first side surface is spaced apart from the contact part in the second direction in the plan view.

17. The display device of claim 15, further comprising:
an auxiliary insulation layer disposed on the inorganic insulation layer and covering the inorganic insulation layer; and
a sub opening defined in the auxiliary insulation layer,
wherein the sub opening overlaps the contact part.

18. The display device of claim 17, wherein
the sub opening overlaps the opening in the plan view, and
a size of the sub opening is smaller than a size of the opening in the plan view.

19. An electronic device, comprising:
a housing;
an electronic module disposed inside the housing; and
a display device disposed on and overlapping the electronic module,
wherein the display device includes:
a base layer including a first area, a second area spaced apart from the first area in a first direction, and a bending area disposed between the first area and the second area;
a first wiring line overlapping the second area and extending in the first direction;
a second wiring line overlapping the bending area and electrically connected to the first wiring line; and
an inorganic insulation layer disposed on the first wiring line, and in which an opening overlapping a contact part, in which the first wiring line and the second wiring line are connected to each other, is defined,
wherein the inorganic insulation layer includes:
a first side surface extending in the first direction;
a second side surface extending in a second direction crossing the first direction; and
a third side surface connecting the first side surface and the second side surface, and having a curved shape in a plan view,
wherein the opening is defined by the first to third side surfaces.

20. The electronic device of claim 19, further comprising:
a driver disposed in the second area; and
a printed circuit board disposed in the second area and electrically connected to the display device.
